(19) United States
(12) Patent Application Publication
(10) Pub. No.: US 2017/0018675 A1
(43) Pub. Date: Jan. 19, 2017

(54) MULTI-JUNCTION PHOTOVOLTAIC MICRO-CELL ARCHITECTURES FOR ENERGY HARVESTING AND/OR LASER POWER CONVERSION

(71) Applicant: Semprius, Inc., Durham, NC (US)

(72) Inventors: Matthew Meitl, Durham, NC (US); Scott Burroughs, Raleigh, NC (US); Brent Fisher, Durham, NC (US); Joseph Carr, Chapel Hill, NC (US)

(21) Appl. No.: 15/280,484

(22) Filed: Sep. 29, 2016

Related U.S. Application Data
(63) Continuation-in-part of application No. 14/683,498, filed on Apr. 10, 2015.
(60) Provisional application No. 62/234,305, filed on Sep. 29, 2015.
(60) Provisional application No. 61/978,569, filed on Apr. 11, 2014.

(51) Int. Cl. H01L 31/16; H01L 31/0304; H01L 31/02; H01L 31/0687; H01L 31/043

(52) U.S. Cl. CPC H01L 31/165; H01L 31/0687; H01L 31/043; H01L 31/02008; H01L 31/03046

(57) ABSTRACT

An optical power converter device includes a light source configured to emit monochromatic light, and a multi-junction photovoltaic cell including respective photovoltaic cell layers having different bandgaps and/or thicknesses. The respective photovoltaic cell layers are electrically connected to collectively provide an output voltage and are vertically stacked relative to a surface of the multi-junction photovoltaic cell that is arranged for illumination by the monochromatic light from the light source. Responsive to the illumination of the surface by the monochromatic light from the light source, the respective photovoltaic cell layers are configured to generate respective output photocurrents that are substantially equal. Related devices and methods of operation are also discussed.

### CLAIM OF PRIORITY

This application is a continuation-in-part of U.S. patent application Ser. No. 14/683,498, entitled “MULTI-JUNCTION POWER CONVERTER WITH PHOTON RECYCLING” and filed Apr. 10, 2015, in the United States Patent and Trademark Office, which claims priority from U.S. Provisional Patent Application No. 61/978,569 entitled “MULTI-JUNCTION LASER POWER CONVERTER WITH PHOTON RECYCLING” filed on Apr. 11, 2014, the disclosures of which are incorporated by reference herein in their entireties. This application also claims priority from U.S. Provisional Patent Application No. 62/234,305 entitled “MULTI-JUNCTION PHOTOVOLTAIC MICRO-CELL ARCHITECTURES FOR ENERGY HARVESTING AND/OR LASER POWER CONVERSION” and filed Sep. 29, 2015, in the United States Patent and Trademark Office, the disclosure of which is incorporated by reference herein in its entirety.

### FIELD

The present disclosure relates to power conversion devices and devices incorporating the same.

### BACKGROUND

Solar cells, including multi-junction solar cells that have substantially similar bandgaps (in which a top cell receives incident light and a second cell subsequently receives any transmitted light), may be used in laser power conversion. Power converters can also include laser power conversion devices in which sub-cell thickness optimization may be used to achieve current matching conditions.

Two-junction or multi-junction laser power converters, where the first cell is about 500 nm-600 nm thick and the second is between about 600 nm and 3000 nm thick and made from GaAs, InGsAsP, InGaP, InGaAlP, InGaAs, GaSb, or AlGaAs, have also been used. Some converters may also include laser power converters with only two junctions in which the band gaps are not similar, as well as laser power converters that deliver illumination via an optical fiber plus atmosphere.

### SUMMARY

Embodiments described herein may be applied in a number of overlapping specific fields, including but not limited to laser power conversion, wearable electronic devices, power transfer, implantable electronics, Internet of Things (IoT), and energy harvesting.

According to some embodiments, an optical power converter device includes a light source configured to emit monochromatic light, and a multi-junction photovoltaic cell including respective photovoltaic cell layers having different bandgaps and/or thicknesses. The respective photovoltaic cell layers are electrically connected to collectively provide an output voltage and are vertically stacked relative to a surface of the multi-junction photovoltaic cell that is arranged for illumination by the monochromatic light from the light source. Responsive to the illumination of the surface by the monochromatic light from the light source, the respective photovoltaic cell layers are configured to generate respective output photocurrents that are substantially equal.

In some embodiments, responsive to the illumination of the surface by the monochromatic light from the light source, the respective photovoltaic cell layers may be configured to generate respective excess photocurrents that are unequal.

In some embodiments, one of the respective photovoltaic cell layers may be configured to generate the respective excess photocurrent in response to the illumination of the surface by the monochromatic light and reemit photons therefrom. Another of the respective photovoltaic cell layers may be configured to generate the respective excess photocurrent in response to absorption of the photons reemitted from the one of the respective photovoltaic cell layers that is vertically stacked thereon.

In some embodiments, at least one of the respective photovoltaic cell layers may have a bandgap and/or thickness such that absorption of the monochromatic light is unequal among the photovoltaic cell layers.

In some embodiments, the respective photovoltaic cell layers may be vertically stacked in order of increasing thickness relative to the surface of the multi-junction photovoltaic cell that is arranged for illumination by the monochromatic light. That is, the thickness of each layer may progressively increase from closer to the light source to further therefrom.

In some embodiments, semiconductor materials of the respective photovoltaic cell layers may be selected to have a range of bandgaps suitable for cascaded luminescent coupling. For example, the respective photovoltaic cell layers may be vertically stacked in order of decreasing bandgap relative to the surface of the multi-junction photovoltaic cell that is arranged for illumination by the monochromatic light.

In some embodiments, the respective photovoltaic cell layers may be lattice matched with respect to one another and/or with respect to a common substrate.

In some embodiments, one of the photovoltaic cell layers that is vertically stacked closer to the surface may be configured to absorb greater than about 90% of a photon energy of the monochromatic light responsive to the illumination of the surface thereby.

In some embodiments, a sum of the different bandgaps of the respective photovoltaic cell layers may exceed a photon energy of the monochromatic light by more than one half electron volt multiplied by a quantity of respective p-n junctions of the stack.

In some embodiments, the respective photovoltaic cell layers may have respective thicknesses within about 10% of one another, and/or two or more of the respective photovoltaic cell layers may have a same bandgap.

In some embodiments, the output voltage may be greater than respective voltages output from the respective photovoltaic cell layers responsive to the illumination. The output voltage may correspond to a charging voltage for a battery of a portable consumer electronics device. The output voltage may be greater than a photon energy of the monochromatic light.

In some embodiments, one of the photovoltaic cells that is vertically stacked closer to the surface may be configured to absorb greater than 1/n of a photon energy of the monochromatic light responsive to the illumination of the surface thereby, where n is the number of photovoltaic cell layers in the multi-junction photovoltaic cell.

In some embodiments, the light source may be a laser light source. The monochromatic light may have a wavelength corresponding to a wavelength range over which the one of the photovoltaic cell layers that is closer to the surface has a maximum quantum efficiency.

In some embodiments, the multi-junction photovoltaic cell and the light source may be assembled on opposite surfaces of a substrate, where the substrate is transparent to a wavelength of the monochromatic light. For example, the substrate may be a lateral conduction layer (LCL) that is configured to extract the respective output photocurrents. The lateral conduction layer may be further transparent to wavelengths of photons reemitted from one or more of the photovoltaic cell layers responsive to the illumination of the surface.

In some embodiments, the multi-junction photovoltaic cell and the light source may be assembled on a high thermal conductivity substrate comprising silicon carbide, silicon, diamond, sapphire, or aluminum nitride.

In some embodiments, the respective photovoltaic cell layers of the multi-junction photovoltaic cell may include one or more transfer-printed photovoltaic cells having respective surface areas of about 4 square millimeters or less.

In some embodiments, the multi-junction photovoltaic cell may be assembled on a substrate that is reflective to a wavelength of the monochromatic light and/or photons reemitted responsive to illumination of the surface thereby. The multi-junction photovoltaic cell may be positioned between the reflective substrate and the light source.

In some embodiments, two or more of the respective photovoltaic cell layers may not be lattice matched to one another.

In some embodiments, the device may further include at least one additional photovoltaic cell layer configured to generate an output current that is substantially equal to the respective output photocurrents of the respective photovoltaic cell layers responsive to illumination thereof by indoor light within a visible wavelength range.

According to further embodiments, a multi-junction photovoltaic cell includes a laser light source configured to emit coherent monochromatic light, and a multi-layer stack comprising respective photovoltaic cell layers that are electrically connected to provide an output voltage The respective photovoltaic cell layers have different bandgaps and/or thicknesses and are vertically stacked relative to a surface of the multi-layer stack that is arranged to for illumination by the coherent monochromatic light. A first one of the respective photovoltaic cell layers that is closer to the laser light source is configured to generate a first output photocurrent and an excess photocurrent such that photons are reemitted therefrom responsive to the illumination of the surface by the coherent monochromatic light. A second one of the respective photovoltaic cell layers that is farther from the laser light source is configured to generate a second output photocurrent responsive to absorption of the photons reemitted from the first one of the respective photovoltaic cell layers. Absorption of the coherent monochromatic light is unequal among the first and second ones of the photovoltaic cell layers, but the first and second output photocurrents are substantially equal.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a block diagram illustrating elements of a laser power conversion system in accordance with some embodiments of the present disclosure.

FIGS. 2A and 2B are cross-sectional views illustrating multi-junction cells that may be used in power conversion systems in accordance with some embodiments of the present disclosure.

FIG. 3 illustrates photon recycling in a three junction power converter that may be used in power conversion systems in accordance with some embodiments of the present disclosure.

FIG. 4 is a cross-sectional view illustrating a multi-junction cell that may be used in power conversion systems in accordance with further embodiments of the present disclosure.

FIG. 5 is a cross-sectional view illustrating a laser power converter including multi-junction cells in accordance with some embodiments of the present disclosure.

FIG. 6 is a cross-sectional view illustrating an example multi-junction power converter assembled on a transparent substrate in accordance with some embodiments of the present disclosure.

FIG. 7 is a cross-sectional view illustrating an example multi-junction power converter assembled on a transparent conduction layer in accordance with some embodiments of the present disclosure.

FIG. 8 is a cross-sectional view illustrating an example multi-junction power converter configured to provide cascaded luminescent coupling in accordance with some embodiments of the present disclosure.

### DETAILED DESCRIPTION OF EMBODIMENTS

Embodiments of the present disclosure provide power converters that may provide higher voltage outputs than possible with traditional single junction power conversion devices. Embodiments of the present disclosure may further employ semiconductor material stacks that are not specifically designed for laser power conversion. Other related advantages according to embodiments of the present disclosure may include the ability to amortize production costs for multi-junction materials across a wider range of devices beyond power converters.

Embodiments of the present disclosure may also achieve less costly and higher voltage output converters that can be more efficiently manufactured, and may allow for the use of less stringent tolerances with respect to the layer thicknesses and/or material bandgaps used in the converters.

Higher voltage output converters according to embodiments of the present disclosure may also use a wider range of light sources with higher efficiency, in addition to monochromatic laser illumination, so as to accommodate wider band illumination from LEDs and other sources.

Higher output voltage converters according to embodiments of the present disclosure may further provide the capability of dual high efficiency conversion, by being able to convert both laser illumination and solar illumination in the same converter. In addition, higher voltage output converters according to embodiments of the present disclosure may also make use of photon recycling to achieve higher current generation.

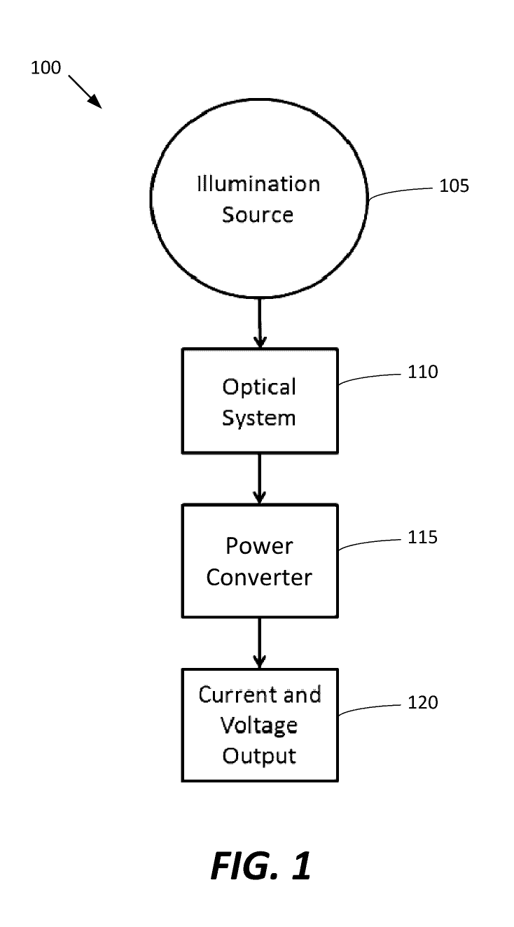

FIG. 1 depicts elements of a laser power conversion system 100 according to some embodiments of the present disclosure that includes an monochromatic illumination source 105, an optical system 110 for delivering illumination, and a power converter 115 (such as a laser power converter), which produces voltage and current output 120. In an example embodiment, the power conversion system 100 of FIG. 1 includes a multi-junction photovoltaic cell that exhibits photon recycling, wherein the structure of the cell is designed or otherwise configured to use the photon recycling to deliver improved performance. In such a cell, the layer thickness of the top cell is designed or otherwise configured to absorb (and thus, produce electric current from) at least a fraction of the incident light greater than 1/n, where n is the number of junctions in the cell.

In the power conversion system 100 of FIG. 1, the illumination source 105 may be a monochromatic laser light source having a wavelength selected for improved or optimal driving of the multi-junction photovoltaic cell. In contrast to some conventional power conversion systems, the operational wavelength of the laser light source is selected to correspond to the quantum efficiency of the various cell layers (generally referred to herein as “cells” or “sub cells”) of the multi-junction photovoltaic cell, such that current generation in each cell is matched or substantially equal when photon recycling is accounted for or otherwise taken into consideration. An optical system 110 provides for transmission or delivery of the light from the light source 105 to the power converter 115. The power converter 115 provides current and voltage output 120 responsive to the light received from the illumination source 105 via the optical system 110.

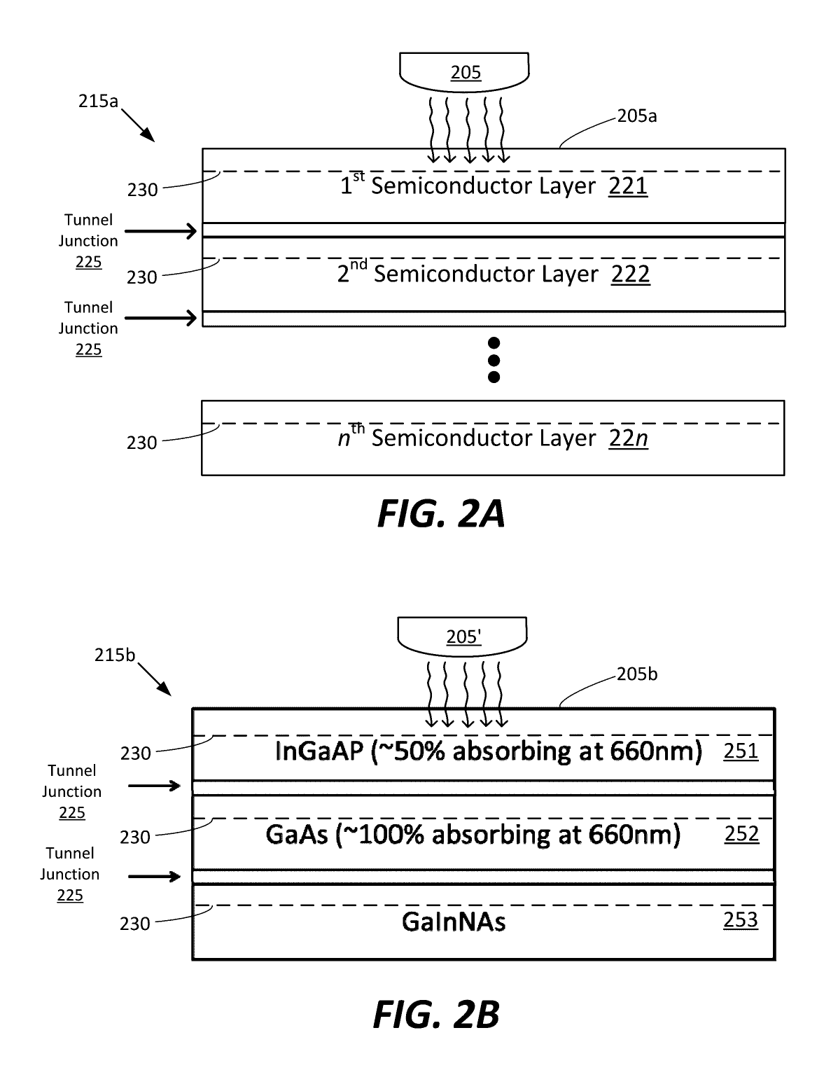

FIG. 2A illustrates an embodiment of the invention where a monochromatic light source 205 is used as the illumination source 105. In the example of FIG. 2A, the power converter 115 includes a multi-junction cell 215a. The multi-junction cell 215a includes a multi-layer stack having n p-n junctions 230 (each junction being or defining a cell 221, 222, . . . 22n, where n is an integer greater than 1) electrically connected in series and separated by low-absorbing tunnel junctions 225 provided between each of the three cells 221, 222, . . . 22n.

The materials of the multi-junction cell 215a of FIG. 2A can be formed by molecular beam epitaxy on a substrate (for example, a gallium arsenide (GaAs) substrate), with lattice matching maintained through some or all layers of material. The multi-junction cell 215a shown in FIG. 2A includes first semiconductor layer 221 defining a top cell, a second semiconductor layer 222 defining a middle cell, and an nth semiconductor layer 22n defining a bottom cell. At least some of the semiconductor layers 222 . . . 22n are vertically stacked in order of decreasing bandgap relative to a surface 205a of the first semiconductor layer 221 of the multi-layer stack, which is positioned or otherwise arranged to receive incident illumination from the light source. For example, the second semiconductor layer 222 may be formed of a semiconductor material having a lower bandgap than that of the first semiconductor layer 221, and the nth semiconductor layer 22n may be formed of a semiconductor material having a lower bandgap than that of the second semiconductor layer 222.

In some embodiments, the multi-junction cell 215a of FIG. 2A can be prepared on a ceramic or silicon substrate using micro transfer printing. For example, arrays of vertically stacked cells can be fabricated using transfer-printing processes similar to those described, for example, in U.S. Pat. No. 7,972,875 to Rogers et al. entitled “Optical Systems Fabricated By Printing-Based Assembly,” the disclosure of which is incorporated by reference herein in its entirety. The individual cells (also referred to herein as ‘subcells’) can be designed or otherwise configured to increase or maximize the capture of light, and may be grown on separate source substrates in some embodiments and assembled using micro-transfer printing as described, for example, in U.S. patent application Ser. No. 14/211,708 to Meitl et al. entitled “High Efficiency Solar Devices Including Stacked Solar Cells For Concentrator Photovoltaics,” the disclosure of which is incorporated by reference herein in its entirety.

FIG. 2B illustrates an embodiment of the invention where a laser monochromatic light source 205′ having a wavelength near 660 nm is used as the illumination source 105. In the example of FIG. 2B, the power converter 115 includes a multi-junction cell 215b. The multi-junction photovoltaic cell 215b has three p-n junctions 230 (each junction being or defining a cell 251, 252, 253) electrically connected in series and separated by low-absorbing tunnel junctions 225 provided between each of the three cells 251, 252, 253.

The materials of the multi-junction cell 215b of FIG. 2B can be formed by molecular beam epitaxy on a GaAs substrate, with lattice matching maintained through some or all layers of material. In particular, the multi-junction cell 215b shown in FIG. 2B includes an InGaP top cell 251 (including an incident light-receiving surface 205b) with a bandgap of about 1.9 eV, a GaAs middle cell 252 with a bandgap of about 1.4 eV, and a dilute nitride bottom cell (illustrated as a GaInNAs cell 253) with a bandgap of about 1.0 eV. The multi-junction cell 215b of FIG. 2B can be prepared on a ceramic or silicon substrate using micro transfer printing. For example, arrays of vertically stacked cells can be fabricated using transfer-printing processes similar to those described, for example, in U.S. Pat. No. 7,972,875 to Rogers et al. The individual cells can be designed or otherwise configured to increase or maximize the capture of light, and may be grown on separate source substrates in some embodiments and assembled using micro-transfer printing as described, for example, in U.S. patent application Ser. No. 14/211,708 to Meitl et al.

Thus, in some embodiments of the present disclosure, a multi-junction laser power converter includes a stack of n junctions (where n is an integer greater than 1), and each of the n junctions are defined by materials having different bandgaps from one another. The topmost junction in the stack (which is positioned nearest to the incident illumination) has the highest bandgap, and each junction below in the stack has a progressively smaller bandgap. Thus, the top junction absorbs substantially more than 1/n of the incident light, while the next junction therebelow absorbs substantially more than 1/(n−1) of the remaining incident light, and similarly for the lower junctions.

According to embodiments of the present disclosure, each cell below the top cell is supplied with additional illumination that has been reemitted from previous cells thereabove in the stack, producing a photon recycling effect. Photon recycling thus distributes or otherwise results in current generation that is substantially similar among the respective cells, in a way that may not be otherwise realized for stacks including junctions having non-equal bandgaps.

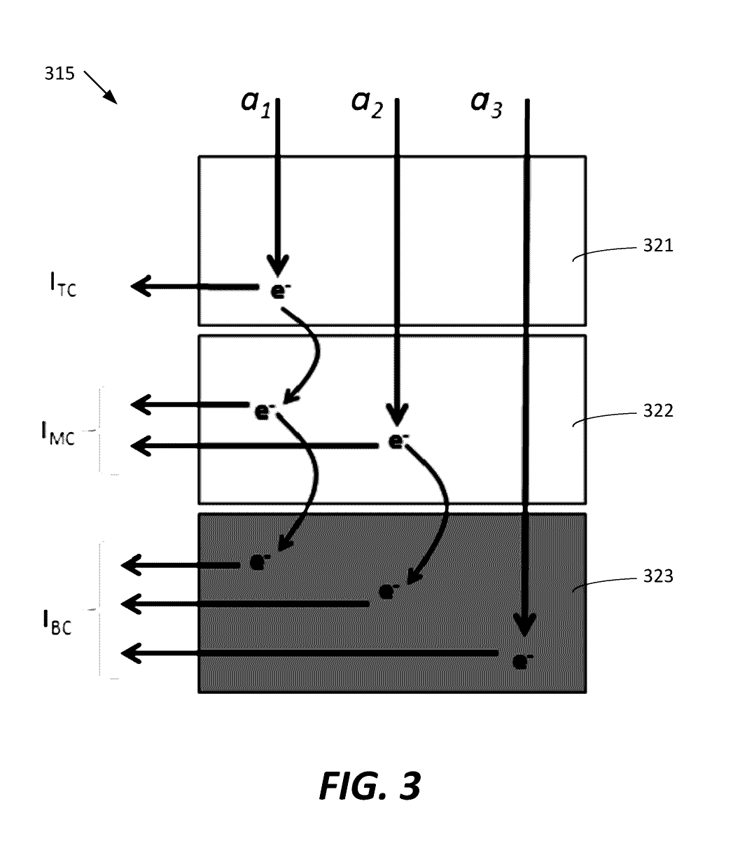

FIG. 3 illustrates photon recycling in a three junction power converter 315. In this illustration, the total current generated by each cell is indicated by Iₓ with horizontal arrows (where x=TC (top cell) 321, MC (middle cell) 322, BC (bottom cell) 323), while the path of incident light photons before being absorbed is indicated by a_{y} with the vertical arrows (where y=1, 2, 3). The symbols e⁻ indicate that photons have been absorbed to create electron-hole pairs in a given material, and the curved arrows indicate that the electron-hole pair has recombined and emitted a photon which is absorbed by a layer below it.

The above process of electron-hole pair recombination and emission of a photon that is reabsorbed by another layer is the process of photon recycling, which may contribute to several advantages provided by embodiments of the invention. The multiplicity of horizontal arrows in the bottom cell 323 compared to the top cell 321 indicates the greater number of pathways by which current can be generated in the lower cells despite the initial absorption of a laser wavelength in the earlier higher bandgap cells. The effect is to increase the current generated by lower-bandgap cells 322, 323 that would not otherwise absorb as high a fraction of the incident light as the top cell 321, by allowing incident photons another chance to be collected by being absorbed in lower-bandgap cells 322, 323. This is a process by which photon recycling enables embodiments of the invention to use materials of non-equal bandgaps that may not be perfectly matched to the illumination wavelength, such that the absorption of the incident light a_{y} into each layer 321, 322, 323 is not equal for all layers 321, 322, 323. As such, multi-junction power converters in accordance with embodiments of the present disclosure may be used with light sources having a wide range of illumination wavelengths, allowing for greater flexibility in the design and use of such devices in a variety of environments.

In some embodiments of the invention, the monochromatic light source is a laser, such as a laser with a wavelength near 660 nm 205′ as shown in FIG. 2B. The multi-junction photovoltaic cell has three junctions electrically connected in series and separated by low-absorbing tunnel junctions. Those tunnel junctions are located in between the three cells. In some embodiments, the materials for multi-junction cells are formed by molecular beam epitaxy (MBE) or Metalorganic Chemical Vapor Deposition (MOCVD) or Organometallic Vapor Phase Epitaxy (OMVPE) on a GaAs substrate with lattice matching maintained through all layers of material. In the example of FIG. 3, the multi-junction cell 315 includes an InGaP top cell 321 with a bandgap of about 1.9 eV, a GaAs middle cell 322 with a bandgap of about 1.4 eV, and a dilute nitride bottom cell with a bandgap of about 1.0 eV. The multi-junction cell 315 may be prepared on a ceramic or silicon substrate using micro transfer printing as described, for example, in U.S. patent application Ser. No. 14/211,708 to Meitl et al.

In some embodiments of the invention, the multi-junction cell may be prepared by dicing the substrate wafer upon which the cell was grown, instead of using micro transfer printing.

In some embodiments the bottom junction may be a germanium cell with a bandgap of 0.7 eV. In further embodiments the bottom cell may be SiGe. In still further embodiments, the bottom cell may be InGaAs. In yet further embodiments, the top and middle cells may be AlGaAs and InGaAIP, respectively. In some embodiments, the light source may be an LED.

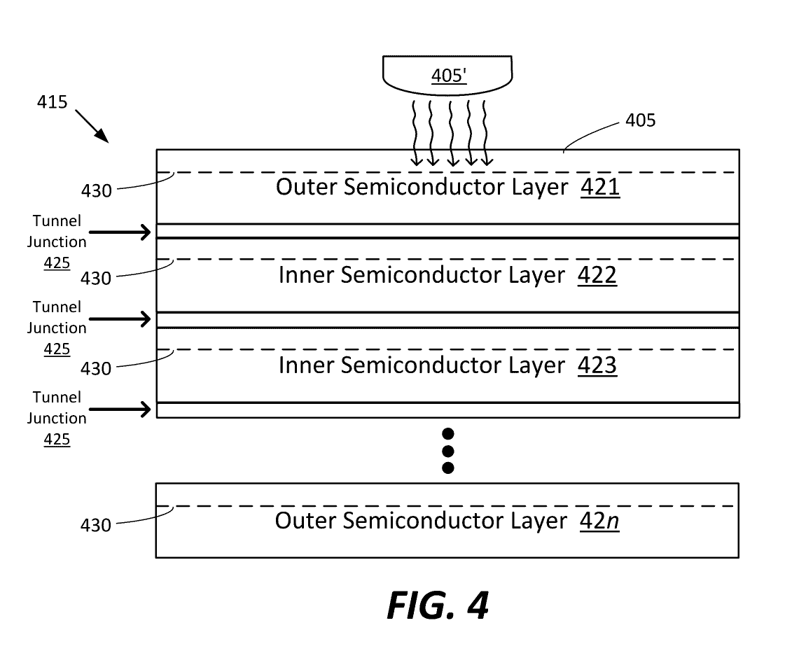

FIG. 4 is a cross-sectional view illustrating a multi-junction cell 415 that may be used in power conversion systems in accordance with further embodiments of the present disclosure. In the example of FIG. 4, a multi-junction cell 415 includes a multi-layer stack having n p-n junctions 430 (each junction being or defining a cell 421, 422, 423 . . . 42n, where n is an integer greater than 1) electrically connected in series and separated by low-absorbing tunnel junctions 425 provided between each of the three cells 421, 422, 423 . . . 42n, where each of the n junctions 430 are defined by semiconductor materials or compounds having the same or similar bandgaps.

The materials of the multi-junction cell 415 of FIG. 4 can be formed by molecular beam epitaxy on a substrate (for example, a gallium arsenide (GaAs) substrate), with lattice matching maintained through some or all layers of material. The multi-junction cell 415 shown in FIG. 4 includes outer semiconductor layers 421 and 42n in the stack 415 defining top and bottom (or exterior) cells, respectively, and inner semiconductor layers 422 and 423 defining interior cells. The outer semiconductor layers 421 and 42n (and their respective junctions 430) are configured to absorb less than 1/n of the incident light on light receiving surface 405, which is emitted from a monochromatic light source 405′, while the inner semiconductor layers 422 and 423 (and their respective junctions 430) are configured to absorb more than 1/n of the incident light. However, the outer semiconductor layers 421 and 42n receive photons that are reemitted from the inner ones of the n junctions in response to the incident light, to produce photon recycling. As such, in the multi-junction cell 415 of FIG. 4, the current generation is substantially equal among the cells 421, 422, 423 . . . 42n.

Thus, in further embodiments, a multi-junction laser power converter includes n junctions (where n is an integer greater than 1), and each of the n junctions are defined by semiconductor materials or compounds having the same or similar bandgaps. Despite unequal absorption of incident light among the cells (for example, where the cell bandgaps are not perfectly matched to the illumination wavelength), the outer cells are supplied with additional illumination that has been reemitted from inner cells in the stack, producing a photon recycling effect. Photon recycling thus distributes or otherwise results in current generation that is substantially similar among the respective cells. As such, multi-junction power converters in accordance with embodiments of the present disclosure may be used with light sources having a wide range of illumination wavelengths, allowing for greater flexibility in the design and use of such devices in a variety of environments.

Although described above primarily with respect to 3-junction cells with reference to particular materials, it will be understood that embodiments of the present disclosure are not so limited. As such, in multi-junction photovoltaic cells in accordance with embodiments of the present disclosure, there may be fewer or more than 3 junctions, using any combinations of the materials mentioned above, or other materials. Also, in some embodiments the cells may be silicon, copper indium gallium selenide (CIGS), or cadmium telluride (CdTe). In other words, the above embodiments are examples of the multiple possible embodiments of the invention and are not intended to be limitations. Other materials and configurations can be used within the scope and spirit of the invention and photon recycling.

Further embodiments of the present disclosure provide devices for efficiently receiving and converting light (for example light from a laser, light emitting diode (LED), incandescent, or fluorescent light source) into electrical energy. Some embodiments provide a miniaturized device by which an active system can receive power, wherein the device is smaller than typical practical alternatives.

In particular, some embodiments of the present disclosure provide device structures that convert monochromatic light into electrical power at standardized or typically-used voltages, e.g. the voltage required to charge batteries including Li-ion batteries, etc. and/or other storage devices including super capacitors, etc. Further embodiments provide device structures that convert monochromatic light into electrical power at voltages that are higher than voltages that are achievable by practical implementations of some conventional laser power converters. Still further embodiments provide device structures that convert indoor light into electrical power at standardized or typically-used voltages, e.g. the voltage required to charge batteries including Li-ion batteries, etc. and/or other storage devices including super capacitors, etc.

In some embodiments of the present disclosure, more than one p-n junction may be formed from or defined by direct band gap semiconductors (for example gallium arsenide, indium phosphide, aluminum gallium arsenide, indium gallium arsenide, indium gallium arsenide phosphide, indium aluminum arsenide, indium gallium arsenide nitride, indium gallium arsenide nitride, and/or their alloys), which are assembled in an electrically connected stack, and having a first p-n junction that is positioned or arranged in the stack to be illuminated by light from an external light source having a first photon energy.

In some embodiments, the stack of p-n junctions may have selected bandgaps such that their summed bandgaps exceeds the photon energy of the external light source by more than one half electron volt multiplied by the number of p-n junctions of the stack.

In some embodiments, the stack of p-n junctions may have different selected bandgaps, thicknesses, and/or absorption characteristics such that the first p-n junction absorbs a fraction of the photon energy of the light incident thereon greater than the fraction one divided by the number of p-n junctions (that is, >1/n, where n is the number of p-n junctions).

In some embodiments, the p-n junctions of the stack may exhibit luminescent coupling, in which some p-n junctions are capable or otherwise configured (under the conditions of illumination) to generate excess photocurrent relative to other p-n junctions, and the excess photocurrent is at least partially converted into light, where one or more of the other p-n junctions are configured to absorb the light generated from the excess photocurrent (and where some of the one or more of the other p-n junctions may not generate excess photocurrent).

Some embodiments of the present disclosure are directed to structures and designs for laser light conversion that can be more practically implementable than some conventional converters (which may require precise balancing of the absorptive characteristics of each p-n junction of the stack for efficient operation). The luminescent coupling of embodiments described herein may allow auto-correction of the photocurrents of the individual p-n junctions of the device, such that the photocurrents generated by each p-n junction of the stack are substantially equal, thereby improving efficiency. Embodiments of the present disclosure can also allow for less stringent manufacturing tolerances of the p-n junctions by a factor of two or more.

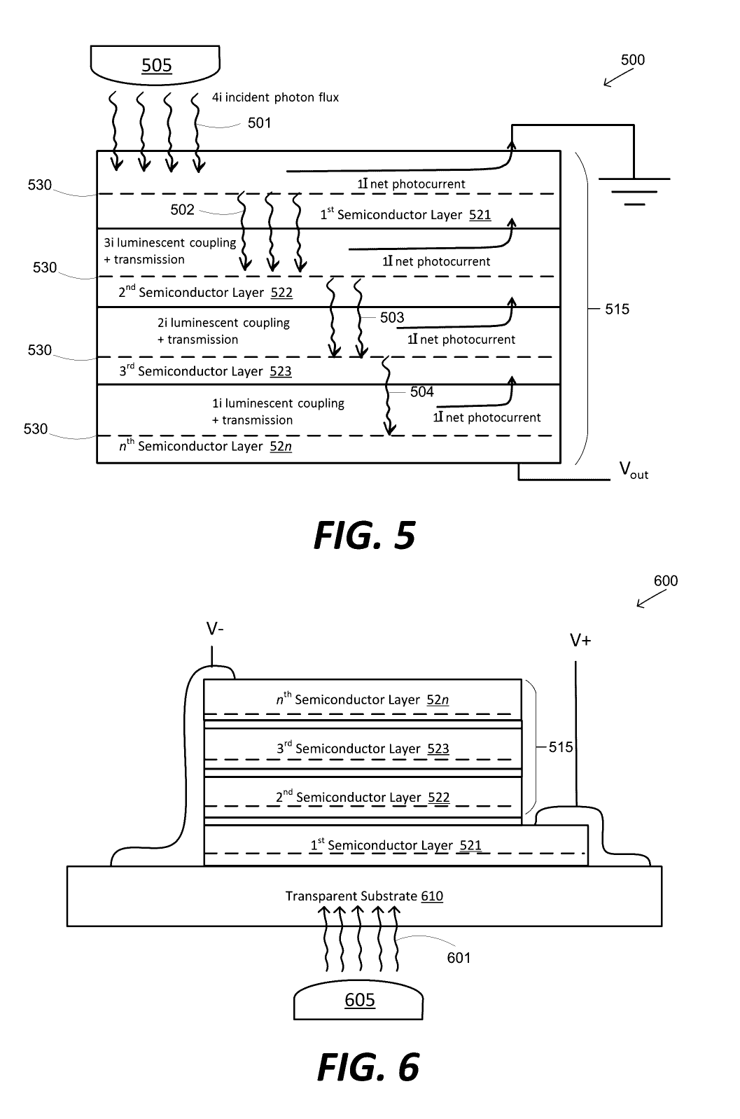

FIG. 5 is a cross-sectional view that illustrates an example laser power converter 500 in accordance with some embodiments of the present disclosure. A monochromatic laser light source 505 is used as the illumination source 105 for a power converter 115 that includes a multi-junction cell 515. The multi-junction cell 515 includes a multi-layer stack having n p-n junctions 530 (each junction being or defining a photovoltaic cell layer 521, 522, 523, . . . 52n, where n is an integer greater than 1) electrically connected in series to collectively provide an output voltage Vout. The stack 515 can thus be configured to provide a desired output voltage Vout (for example, as required to charge a battery of a portable consumer electronics device) by selection of the number of p-n junctions n in the stack 515. In some embodiments, the photovoltaic cell layers 521, 522, 523, . . . 52n may be separated by low-absorbing tunnel junctions therebetween.

The wavelength of the laser light source 505 and the characteristics (e.g., materials and/or thicknesses) of the various photovoltaic cell layers 521, 522, 523, . . . 52n (also referred to herein as “cells” or “sub cells”) are selected to correspond to one another such that the net photocurrent generated in each cell layer in response to the light incident thereon is matched or substantially equal, even if there is unequal absorption of the monochromatic light among the photovoltaic cell layers 521, 522, 523, . . . 52n in some embodiments. For example, the photovoltaic cell layers 521, 522, 523, . . . 52n may be formed from respective semiconductor materials having different bandgaps and/or thicknesses that are not perfectly matched to the illumination wavelength of the incident light 501, such that some cell layers are supplied with additional illumination that has been reemitted from other cell layers in the stack, producing a photon recycling or luminous coupling effect.

In the example of FIG. 5, the symbol “i” is used to indicate a unit of incident photon flux, while the symbol “I” is used to indicate a unit of output photocurrent. As shown in FIG. 5, the laser light source 505 emits narrowband, coherent monochromatic light 501 (and in some embodiments, light of a substantially single wavelength) that is incident on the first semiconductor layer 521 of the multi-junction cell 515, which is positioned closest to the laser light source among the layers of the stack 515. An entirety of the incident light 501 (illustrated as 4i units) is thus incident on the first semiconductor layer 521. In response to illumination by the incident light 501, the p-n junction 530 of the first semiconductor layer 521 converts at least a portion of the incident light 501 into current, which is output as a net photocurrent of 1I, and generates a first amount of excess photocurrent that is converted by photon re-emission into reemitted light 502 (illustrated as 3i units). The reemitted light 502 output from the first semiconductor layer 521 thus has a photon energy that is lower than that of the incident light 501 emitted from the light source 505. In some embodiments, the first p-n junction 530 may be configured to absorb a fraction of the incident light 501 that is greater than 1/n (where n is the number of p-n junctions 530 in the stack 515).

Still referring to FIG. 5, the reemitted light 502 is transmitted to the second semiconductor layer 522, which is positioned below the first semiconductor layer 521 in the stack 515. The p-n junction 530 of the second semiconductor layer 522 converts a portion of the reemitted light 502 incident thereon into net photocurrent 1I for output, and generates a second amount of excess photocurrent that is converted by photon emission into reemitted light 503 (illustrated as 2i units). The reemitted light 503 output from the second semiconductor layer 522 due to luminescent coupling thus has a photon energy that is lower than that of the reemitted light 502 output from the first semiconductor layer 521. The reemitted light 503 is similarly transmitted to the third semiconductor layer 523, which is positioned below the second semiconductor layer 522 in the stack 515.

The p-n junction 530 of the third semiconductor layer 523 likewise converts a portion of the reemitted light 503 into net photocurrent 1I for output, and generates a third amount of excess photocurrent that is converted by photon emission into reemitted light 504 (illustrated as 1i unit). The reemitted light 504 output from the third semiconductor layer 523 due to luminescent coupling thus has a photon energy that is lower than that of the reemitted light 503 output from the second semiconductor layer 522, and is similarly transmitted to the n^{th} semiconductor layer 52n positioned therebelow in the stack 515, whose p-n junction in turn converts the reemitted light 504 into photocurrent 1I for output. As such, each of the photovoltaic cell layers 521, 522, 523, . . . 52n of the stack 515 outputs a substantially equal photocurrent (within a factor of two, for example) due to luminescent coupling between adjacent ones of the layers 521, 522, 523, . . . 52n, despite unequal generation of excess photocurrent and/or absorption among the layers 521, 522, 523, . . . 52n with respect to the wavelengths of the incident light 505.

The net photocurrents 1I may be equalized, for example, based on selection of layer material/bandgap and/or layer thickness, as well as selection of the wavelength of the incident light 501 emitted from the laser light source 505. For example, the second semiconductor layer 522 may be formed of a semiconductor material having a lower bandgap and/or greater thickness than that of the first semiconductor layer 521, the third semiconductor layer 523 may be formed of a semiconductor material having a lower bandgap and/or greater thickness than that of the second semiconductor layer 522, and the nth semiconductor layer 52n may be formed of a semiconductor material having a lower bandgap and/or greater thickness than that of the third semiconductor layer 523. The materials of the multi-junction cell 515 of FIG. 5 can be formed such that lattice matching is not maintained through some or all of the layers 521, 522, 523, . . . 52n. In other embodiments, the materials of the multi-junction cell 515 of FIG. 5 can be formed such that lattice matching is maintained through some or all of the layers 521, 522, 523, . . . 52n.

In some embodiments, the net photocurrent generated by each cell layer of the stack may include a first current component representing the current generated in response to portions of the incident light that are transmitted thereto (illustrated by vertical arrows in FIG. 3), and a second current component representing the current generated in response to luminescent coupling or photon recycling between adjacent ones of the cell layers (illustrated by curved arrows in FIG. 3). The first current component of one or more of the cell layers may be unequal relative to one another. Likewise, the second current component of one or more of the cell layers may be unequal relative to one another.

In FIG. 5, the number of layers n in the stack is selected such that the final or n^{th} semiconductor layer 52n of the stack does not generate excess photocurrent in response to the reemitted light 504 incident thereon, by way of example only. As such, it will be understood that embodiments of the present disclosure are not limited to such an arrangement, and may include fewer or more cell layers such that some or all layers generate excess photocurrent that is reemitted to a layer below. For example, some embodiments may include the n^{th} semiconductor layer 52n on a surface of a substrate that is reflective to the wavelength(s) of light, such that excess photocurrent that is generated and reemitted therefrom is reflected by the reflective substrate back towards the first semiconductor layer 521 and the light source 505, providing further potential for absorption. Also, while illustrated as a laser light source 505, in some embodiments the monochromatic illumination source may be implemented using an LED. An optical system (such as the optical system 110 of FIG. 1) provides for transmission or delivery of the light from the light source 505 to the power converter 515.

FIG. 6 is a cross-sectional view illustrating an example multi-junction power converter 600 assembled on a transparent substrate 610 in accordance with some embodiments of the present disclosure. As shown in FIG. 6, the stack of p-n junctions 515 of FIG. 5 is formed or otherwise provided on a surface of a transparent substrate 610. A monochromatic light source 605, such as a laser light source, is positioned on or adjacent an opposing surface of the substrate 610, where the substrate 610 is transparent with respect to the wavelength range of the monochromatic light 601 emitted by the monochromatic light source 605. For example, the transparent substrate 610 may be a sapphire or glass substrate, and the stack of p-n junctions 515 may be printed, formed, or otherwise assembled on the sapphire or glass substrate such that the monochromatic light 601 emitted thereby travels through the transparent substrate 610 prior to absorption by the first p-n junction 530 of the first semiconductor layer 521. In further embodiments, the stack of p-n junctions 515 can be printed, formed, or otherwise assembled on a high thermal conductivity substrate, for example, silicon carbide, silicon, diamond, sapphire, or aluminum nitride.

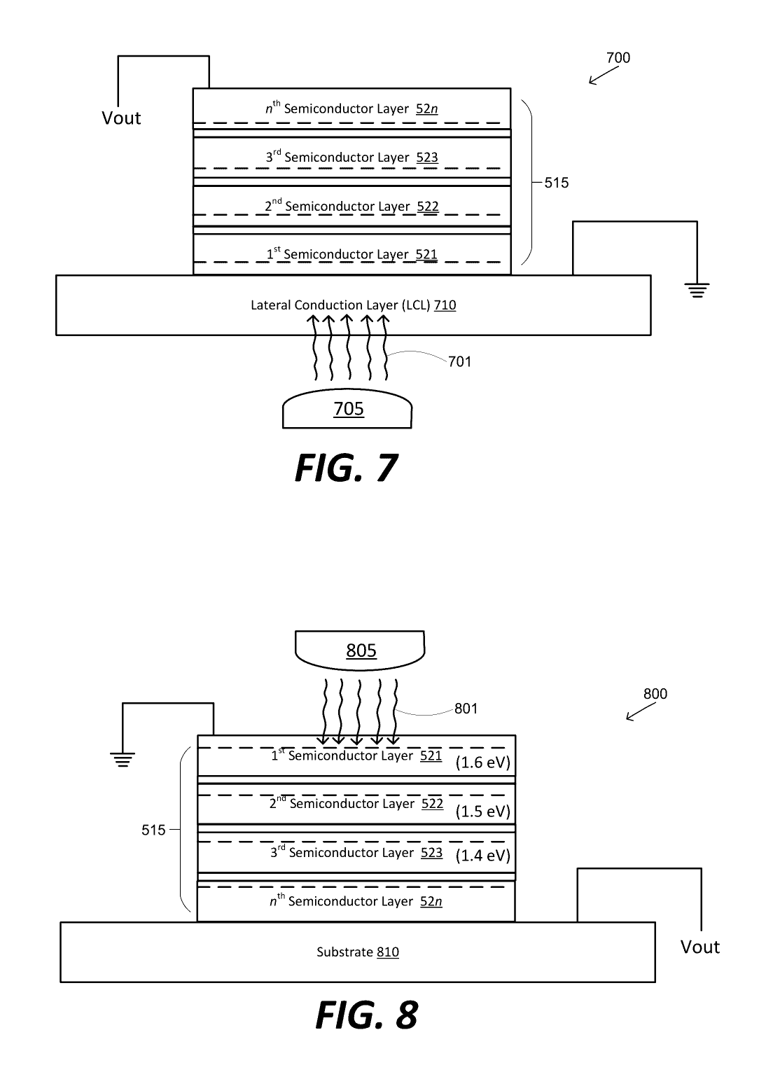

FIG. 7 is a cross-sectional view illustrating an example multi-junction power converter 700 assembled on a transparent conduction layer 710 in accordance with some embodiments of the present disclosure. As shown in FIG. 7, the stack of p-n junctions 515 is printed, formed, or otherwise assembled on a transparent lateral conduction layer (LCL) 710. The LCL 710 is formed from a material that is transparent with respect to the wavelength range of the monochromatic light 701 emitted from the monochromatic light source 705. Examples of materials that may be used as transparent lateral conduction layers 710 include, but are not limited to, highly n-type doped gallium arsenide, aluminum arsenide, indium phosphide, indium gallium phosphide, indium aluminum arsenide, and indium gallium aluminum arsenide.

Still referring to FIG. 7, the stack 515 is electrically coupled to the LCL 710 to extract photocurrent generated by the layers 521, 522, 523, . . . 52n. As the LCL 710 is transparent with respect to the monochromatic light 701, the transparent LCL 710 can be positioned or arranged between the monochromatic light source 705 and the stack 515. The LCL 710 thus does not absorb incident light 701 from the intended external source 705 or light from luminescent coupling between p-n junctions 530 of the stack 515. In the example of FIG. 7, the highest bandgap layer 521 is provided directly on the LCL 710; however, it will be understood that embodiments of the present disclosure can include other arrangements of the LCL 710 relative to the stack 515.

The various stacks of p-n junctions that define the multi-junction photovoltaic cells described herein may be formed using methods of micro-transfer printing. As such, the photovoltaic cell layers of the stacks may each have a respective surface area of less than about 4 square millimeters or less. In some embodiments, the stack of p-n junctions can be formed by transfer printing one or more photovoltaic cell layers into optical contact with one or more other photovoltaic cell layers. Also, the stack of p-n junctions may include one or more photovoltaic layers comprising materials that are not lattice matched to one another.

FIG. 8 is a cross-sectional view illustrating an example multi-junction power converter 800 configured to provide cascaded luminescent coupling in accordance with some embodiments of the present disclosure. As shown in FIG. 8, the stack of p-n junctions 515 are printed, formed, or otherwise assembled on a substrate 810 such that the photovoltaic cell layers 521, 522, 523, . . . 52n are arranged in order of highest bandgap (layer 521) to lowest bandgap (layer 52n), with the lowest bandgap layer 52n provided on the surface of the substrate 810. The monochromatic light source 805 is arranged to provide incident illumination 801 on the highest bandgap layer 521.

The layers 521, 522, 523, . . . 52n are thus arranged to form a cascade of luminescent coupling, in which the p-n junctions 530 of the stack 515 are arranged in order of highest bandgap to lowest bandgap relative to the monochromatic light source 805, wherein incident light 801 impinges upon a p-n junction 530 of the first semiconductor layer 521 having a first bandgap (illustrated by way of example as 1.6 eV), and reemitted light from the p-n junction 530 of the first semiconductor layer 521 is absorbed by a p-n junction 530 of the second semiconductor layer 522, which has a second bandgap (illustrated by way of example as 1.5 eV) that is lower than the first bandgap. The p-n junction 530 of the second semiconductor layer 522 generates a second amount of reemitted light that has a photon energy corresponding to the second bandgap of the second semiconductor layer 522, which is lower than the photon energy of the first amount of reemitted light. A p-n junction 530 of the third semiconductor layer 523, having a third bandgap (illustrated by way of example as 1.4 eV) that is lower than the second bandgap of the second semiconductor layer 522, absorbs at least a portion of the second amount of reemitted light, and so forth, until all p-n junctions 530 of the layers 521, 522, 523, . . . 52n have an acceptably-matched (within a factor of two, for example) output photocurrent.

In the example of FIG. 8, the photovoltaic cell layers 521, 522, 523, . . . 52n may be formed from p-n junction materials systems including but not limited to aluminum gallium arsenide of various compositions, indium gallium arsenide phosphide of various compositions, indium aluminum gallium phosphide of various compositions, and/or indium gallium nitride arsenide of various compositions, some or all of which may be grown lattice matched to a commonly available substrate and selected to have a range of bandgaps suitable for cascaded luminescent coupling. In some embodiments, the first p-n junction 530 of the first semiconductor layer 521 can absorb substantially all (e.g., greater than about 90%) of the incident light 801.

In some embodiments, some or all of the photovoltaic cell layers 521, 522, 523, . . . 52n defining the p-n junctions 530 of the stack 515 may have substantially the same thickness (e.g., thicknesses within 10% of one another, for example, within about one micron).

In some embodiments, some or all of the photovoltaic cell layers 521, 522, 523, . . . 52n defining the p-n junctions 530 of the stack 515 have different thicknesses (e.g., the thicknesses of each layer may progressively increase from closer to the incident light source to further therefrom). For example, the thickness of one or more layers may be selected in order to match the excess photocurrent generated by the layer thereabove.

In some embodiments, a reflector (e.g., a mirror) may be formed or otherwise provided in optical contact with the stack 515, opposite the monochromatic light source that provides the incident light.

Although generally described herein with reference to multi-junction photovoltaic cells including photovoltaic cell layers defined by semiconductor materials of different bandgaps, in some embodiments, two or more photovoltaic cell layers of the stack may be formed of semiconductor materials having the same bandgap. Also, although generally illustrated herein with reference to multi-junction photovoltaic cells having four photovoltaic cell layers in each stack, fewer or more layers may be provided in accordance with embodiments of the present disclosure. For example, in some embodiments, the stack of photovoltaic cell layers may include four or more p-n junctions. In some embodiments, the stack of photovoltaic cell layers may include eight or more p-n junctions. Moreover, although described primarily herein with reference to p-n junctions, embodiments of the present disclosure may be implemented by photovoltaic cells formed from semiconductor junctions other than p-n junctions, for example, p-i-n junctions, Schottky junctions, etc. In other words, embodiments of the present disclosure are described with reference to specific types of photovoltaic cells by way of example, but other types of photovoltaic cells may be used in accordance with the embodiments described herein.

The present disclosure has been described above with reference to the accompanying drawings, in which embodiments are shown. However, this invention should not be construed as limited to the embodiments set forth herein. Rather, these embodiments are provided so that this disclosure will be thorough and complete, and will fully convey the scope of embodiments of the present disclosure to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of embodiments of the present disclosure.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description herein is for the purpose of describing particular embodiments only and is not intended to be limiting of embodiments of the present disclosure. As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of embodiments of the present disclosure.

Unless otherwise defined, all terms used in disclosing embodiments, including technical and scientific terms, have the same meaning as commonly understood by one of ordinary skill in the art to which this invention belongs, and are not necessarily limited to the specific definitions known at the time of the present disclosure. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Aspects of the present disclosure are described herein with reference to flowchart illustrations and/or block diagrams of methods and systems according to embodiments. It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

Although described herein with reference to various embodiments, it will be appreciated that further variations and modifications may be made within the scope and spirit of the principles of the present disclosure. Although specific terms are employed, they are used in a generic and descriptive sense only and not for purposes of limitation, the scope of the present disclosure being set forth in the following claims.

That which is claimed:

1. An optical power converter device, comprising:
a light source configured to emit monochromatic light; and
a multi-junction photovoltaic cell comprising respective photovoltaic cell layers having different bandgaps and/or thicknesses, wherein the respective photovoltaic cell layers are electrically connected to collectively provide an output voltage and are vertically stacked relative to a surface of the multi-junction photovoltaic cell that is arranged for illumination by the monochromatic light from the light source,
wherein, responsive to the illumination of the surface by the monochromatic light from the light source, the respective photovoltaic cell layers are configured to generate respective output photocurrents that are substantially equal.

2. The device of claim 1, wherein, responsive to the illumination of the surface by the monochromatic light from the light source, the respective photovoltaic cell layers are configured to generate respective excess photocurrents that are unequal.

3. The device of claim 2, wherein:
one of the respective photovoltaic cell layers is configured to generate the respective excess photocurrent in response to the illumination of the surface by the monochromatic light and reemit photons therefrom; and
another of the respective photovoltaic cell layers is configured to generate the respective excess photocurrent in response to absorption of the photons reemitted from the one of the respective photovoltaic cell layers that is vertically stacked thereon.

4. The device of claim 2, wherein at least one of the respective photovoltaic cell layers comprises a bandgap and/or thickness such that absorption of the monochromatic light is unequal among the photovoltaic cell layers.

5. The device of claim 4, wherein the respective photovoltaic cell layers are vertically stacked in order of increasing thickness relative to the surface of the multi-junction photovoltaic cell that is arranged for illumination by the monochromatic light.

6. The device of claim 4, wherein the respective photovoltaic cell layers are vertically stacked in order of decreasing bandgap relative to the surface of the multi-junction photovoltaic cell that is arranged for illumination by the monochromatic light.

7. The device of claim 4, wherein one of the photovoltaic cell layers that is vertically stacked closer to the surface is configured to absorb greater than about 90% of a photon energy of the monochromatic light responsive to the illumination of the surface thereby.

8. The device of claim 1, wherein a sum of the different bandgaps of the respective photovoltaic cell layers exceeds a photon energy of the monochromatic light by more than one half electron volt multiplied by a quantity of respective p-n junctions of the multi-junction photovoltaic cell.

9. The device of claim 1, wherein the respective photovoltaic cell layers have respective thicknesses within about 10% of one another, and/or wherein two or more of the respective photovoltaic cell layers have a same bandgap.

10. The device of claim 1, wherein the output voltage is greater than respective voltages output from the respective photovoltaic cell layers responsive to the illumination, and corresponds to a charging voltage for a battery of a portable consumer electronics device.

11. The device of claim 1, wherein one of the photovoltaic cell layers that is vertically stacked closer to the surface is configured to absorb greater than 1/n of a photon energy of the monochromatic light responsive to the illumination of the surface thereby, where n is the number of photovoltaic cell layers in the multi-junction photovoltaic cell.

12. The device of claim 11, wherein the light source comprises a laser light source, and wherein the monochromatic light has a wavelength corresponding to a wavelength range over which the one of the photovoltaic cell layers that is closer to the surface has a maximum quantum efficiency.

13. The device of claim 1, wherein the multi-junction photovoltaic cell and the light source are assembled on opposite surfaces of a substrate, wherein the substrate is transparent to a wavelength of the monochromatic light.

14. The device of claim 13, wherein the substrate is a transparent lateral conduction layer (LCL) that is configured to extract the respective output photocurrents, wherein the lateral conduction layer is further transparent to wavelengths of photons reemitted from one or more of the photovoltaic cell layers responsive to the illumination of the surface.

15. The device of claim 1, wherein the multi-junction photovoltaic cell and the light source are assembled on a substrate, wherein the substrate is a high thermal conductivity substrate comprising silicon carbide, silicon, diamond, sapphire, or aluminum nitride.

16. The device of claim 1, wherein the respective photovoltaic cell layers of the multi-junction photovoltaic cell comprise one or more transfer-printed photovoltaic cells having respective surface areas of about 4 square millimeters or less.

17. The device of claim 1, wherein the multi-junction photovoltaic cell is assembled on a substrate that is reflective to a wavelength of the monochromatic light and/or photons reemitted responsive to illumination of the surface thereby, wherein the multi-junction photovoltaic cell is positioned between the reflective substrate and the light source.

18. The device of claim 1, wherein two or more of the respective photovoltaic cell layers are not lattice matched to one another.

19. The device of claim 1, further comprising at least one additional photovoltaic cell layer that is configured to generate an output current that is substantially equal to the respective output photocurrents of the respective photovoltaic cell layers responsive to illumination thereof by light within a visible wavelength range.

20. A multi-junction photovoltaic cell, comprising:
a laser light source configured to emit coherent monochromatic light; and
a multi-layer stack comprising respective photovoltaic cell layers that are electrically connected to provide an output voltage, wherein the respective photovoltaic cell layers have different bandgaps and/or thicknesses and are vertically stacked relative to a surface of the multi-layer stack that is arranged to for illumination by the coherent monochromatic light,
wherein a first one of the respective photovoltaic cell layers that is closer to the laser light source is configured generate a first output photocurrent and an excess photocurrent such that photons are reemitted therefrom responsive to the illumination of the surface by the coherent monochromatic light,
wherein a second one of the respective photovoltaic cell layers that is farther from the laser light source is configured to generate a second output photocurrent responsive to absorption of the photons reemitted from the first one of the respective photovoltaic cell layers,
wherein absorption of the coherent monochromatic light is unequal among the first and second ones of the photovoltaic cell layers, and wherein the first and second output photocurrents are substantially equal.
